(19) United States
(12) Patent Application Publication
(10) Pub. No.: US 2013/0119459 A1
(43) Pub. Date: May 16, 2013

(54) SEMICONDUCTOR DEVICE AND METHOD FOR MANUFACTURING THE SAME

(71) Applicant: Woo Young CHUNG, Yongin-si (KR)

(72) Inventor: Woo Young CHUNG, Yongin-si (KR)

(73) Assignee: Hynix Semiconductor Inc., Icheon-si (KR)

(21) Appl. No.: 13/347,558

(22) Filed: Jan. 10, 2012

(30) Foreign Application Priority Data
Nov. 11, 2011 (KR) 10-2011-0117854

(51) Int. Cl. H01L 29/78

(52) U.S. Cl. 257/329; 257/E29.262

(57) ABSTRACT

A semiconductor device and a method for manufacturing the same are disclosed, which form a bit line only at one side of a line pattern by partially etching a semiconductor substrate in a vertical gate structure, such that a body tied structure for reducing the floating body effect can be implemented. A semiconductor device includes a line pattern formed over a semiconductor substrate, a bit line buried in a bottom part of one side of the line pattern, and a gate formed over the bit line, and located perpendicular to the bit line.

### CROSS-REFERENCE TO RELATED APPLICATION

The priority of Korean patent application No. 10-2011-0117854 filed on 11 Nov. 2011, the disclosure of which is hereby incorporated in its entirety by reference, is claimed.

### BACKGROUND OF THE INVENTION

Embodiments of the present invention relate to a semiconductor device, and more particularly to a semiconductor device including a vertical gate and a method for manufacturing the same.

As the integration degree of a semiconductor device is increased, a channel length of a transistor is gradually decreased. However, the reduction in channel length of the transistor increases the occurrence of a Drain Induced Barrier Lowering (DIBL) phenomenon, a hot carrier effect, and a short channel effect such as punch-through. In order to solve such problems, a variety of methods are being intensively researched by many developers and companies, for example, a method for reducing a depth of a junction region, a method for increasing a relative channel length by forming a recess in a channel region of a transistor, and the like.

However, as integration density of a semiconductor memory device (especially, Dynamic Random Access Memory (DRAM)) approaches Gigabits, it becomes necessary to manufacture a smaller-sized transistor. Therefore, although the channel length is scaled using a current planer transistor in which a gate electrode is formed over a semiconductor substrate and a junction region is formed at both sides of the gate electrode, it becomes difficult to satisfy a required device area. In order to solve the above-mentioned problems, a vertical channel transistor structure has recently been proposed.

However, a vertical channel transistor structure according to the related art has been designed to use a double gate and a double bit line. If the double bit line is formed at both sides of the line pattern, a floating body severed from the semiconductor substrate formed. The above-mentioned floating body is referred to as a floating body effect. If the floating body effect occurs, a Bipolar Junction Transistor (BJT) is formed, resulting in a deterioration of retention time.

### BRIEF SUMMARY OF THE INVENTION

Various embodiments of the present invention are directed to providing a semiconductor device and a method for manufacturing the same that substantially obviate one or more problems due to limitations and disadvantages of the related art.

An embodiment of the present invention relates to a semiconductor device and a method for manufacturing the same, which form a bit line only at one side of a line pattern by partially etching a semiconductor substrate in a vertical gate structure, such that a body tied structure for reducing the floating body effect can be implemented.

In accordance with an aspect of the present invention, a semiconductor device includes a line pattern formed over a semiconductor substrate; a bit line buried in a bottom part of one side of the line pattern; and a gate formed over the bit line, and located perpendicular to the bit line.

The line pattern may be formed by etching the semiconductor substrate. The bit line may be formed in a bulb shape. The bit line may be formed of any one of a titanium (Ti) film, a titanium nitride (TiN) film, a tungsten (W) film, and a combination thereof.

The semiconductor device may further include a plurality of pillar patterns formed over the line pattern.

The pillar pattern may be formed by etching an upper part of the line pattern. The gate may be formed at both sides of the pillar pattern. The gate may be formed to interconnect the plurality of pillar patterns.

In accordance with another aspect of the present invention, a method for manufacturing a semiconductor device includes forming a plurality of line patterns over a semiconductor substrate; forming a recess by etching a bottom part of one side of the line pattern; forming a bit line by burying a conductive material in the recess; forming a plurality of pillar patterns by etching an upper part of the line pattern; and forming a gate vertically crossing the bit line at both sides of each pillar pattern.

The forming the recess may include forming a polysilicon layer over the semiconductor substrate including the line pattern; implanting ions in the polysilicon layer that is formed not only over a bottom part of one side of the line pattern but also over the semiconductor substrate adjacent to the bottom part of one side of the line pattern; removing the ion-implanted polysilicon layer, and exposing the bottom part of one side of the line pattern and the surface of the semiconductor substrate adjacent to the bottom part of one side of the line pattern; and etching the exposed line pattern and the exposed semiconductor substrate. The implanting the ions in the polysilicon layer may be performed two times.

The implanting the ions in the polysilicon layer may include performing a primary ion implantation process in the polysilicon layer formed over the semiconductor substrate disposed between the line patterns; and performing a secondary ion implantation process in the polysilicon layer formed over a surface of the bottom part of one side of the line pattern.

Each of the primary ion implantation process and the second ion implantation process may be performed by tilt ion implantation, and the primary ion implantation process may be performed in the opposite direction to the secondary ion implantation process. The primary ion implantation may be performed at a tilt angle of 5°˜10° with respect to the surface of the semiconductor substrate. The secondary ion implantation may be performed at a tilt angle of 10°˜15° with respect to the surface of the semiconductor substrate.

The etching the exposed line pattern and the exposed semiconductor substrate may be performed by an isotropic etching process.

The forming the bit line by burying the conductive material in the recess may further include forming a bit line conductive material over the semiconductor substrate including the recess; and etching the polysilicon layer and the bit line conductive material until the semiconductor substrate between the line patterns is exposed. In the forming the bit line by burying the conductive material, the conductive material may be formed of any one of a titanium (Ti) film, a titanium nitride (TiN) film, a tungsten (W) film, and a combination thereof.

The forming the plurality of pillar patterns may include forming an insulation film over an entire surface of the semiconductor substrate including a line pattern in which the bit line is formed; forming a mask pattern vertically crossing the line pattern over the insulation film and the line pattern; and etching the insulation film and the line pattern using the mask pattern as an etch mask.

The forming the gate may include forming a gate conductive material at a bottom part between the pillar patterns; forming a spacer over the gate conductive material located at sidewalls of the pillar patterns; and etching the gate conductive material using the spacer as an etch mask.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is perspective and cross-sectional views illustrating a semiconductor device according to an embodiment of the present invention.

FIGS. 2A to 2I are perspective and cross-sectional views illustrating a method for manufacturing a semiconductor device according to an embodiment of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts. A semiconductor device and a method for manufacturing the same according to embodiments of the present invention will hereinafter be described with reference to the accompanying drawings.

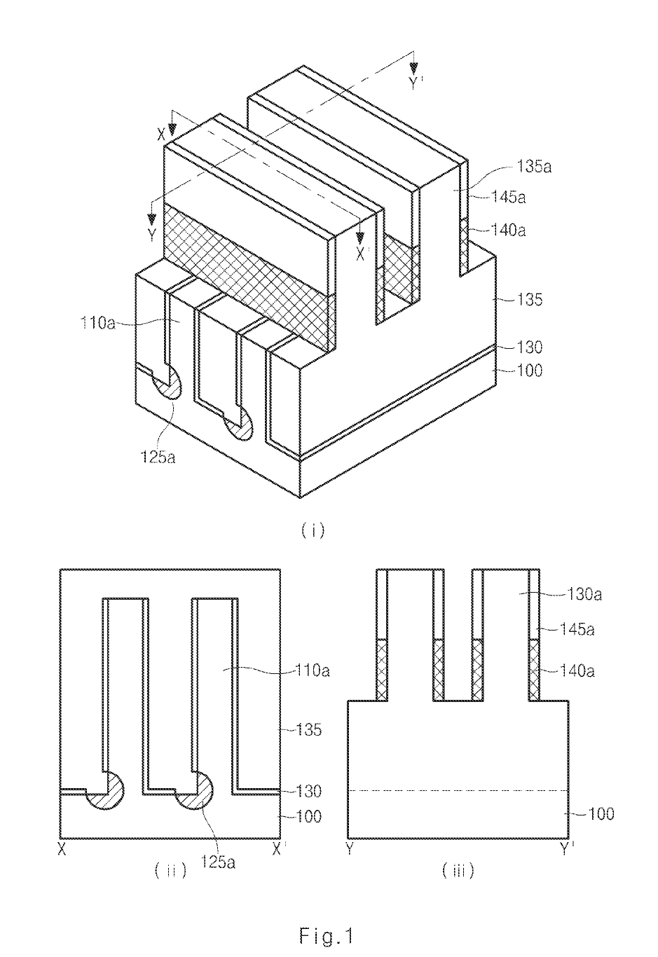

FIG. 1 is perspective and cross-sectional views illustrating a semiconductor device according to an embodiment of the present invention. FIG. 1(ii) is a cross-sectional view illustrating a semiconductor device taken along the line X-X′ of FIG. 1(i). FIG. (iii) is a cross-sectional view illustrating a semiconductor device taken along the line Y-Y′ of FIG. 1(i).

Referring to FIG. 1, the semiconductor device includes a bit line 125a buried in the bottom of one side of the line pattern 110, and a gate 140a formed perpendicular to the bit line 125a. Constituent elements of the semiconductor will hereinafter be described in detail. A line pattern 110 is formed by etching the semiconductor substrate 100, and a bulb-shaped bit line 125a is buried in the bottom of one side of the line pattern 110. In an embodiment, the bit line 125a extends below line pattern 110 without isolating the line pattern from the body of the substrate in order to avoid a floating body effect that degrades the retention time of the semiconductor device. The bit line 125a is not limited only to the bulb shape, and can also be applied to other shapes as necessary. The bit line 125a may include any one of a titanium (Ti) film, a titanium nitride (TiN) film, a tungsten (W) film, and a combination thereof. Preferably, the bit line 125a may include a laminate structure of titanium (Ti) film and titanium nitride (TiN) film or a laminate structure of titanium nitride (TiN) film and tungsten (W) film.

An extended gate 140a is formed over the resultant bit line 125a in such a manner that the gate 140a is formed perpendicular to the bit line 125a. The gate 140a is formed at both sides of each pillar pattern 110a formed by etching an upper part of the line pattern 110, and may be formed to interconnect a plurality of pillar patterns 110a.

As described above, the bit line 125a is formed near the bottom of the line pattern 110 and only on one side. This allows the line pattern 110 structure to be tied to the body reducing the floating body effect in the typical vertical gate.

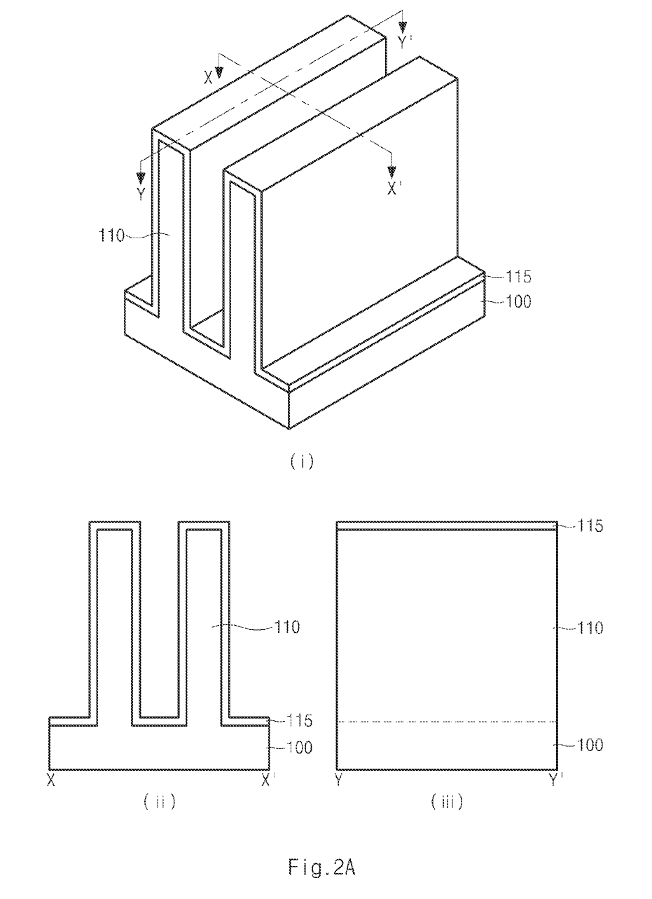

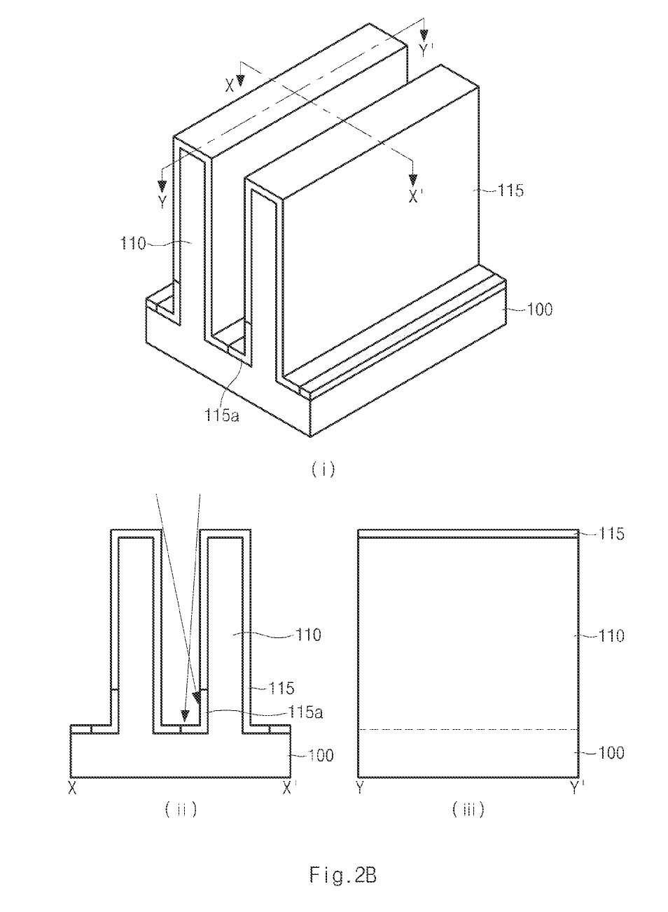

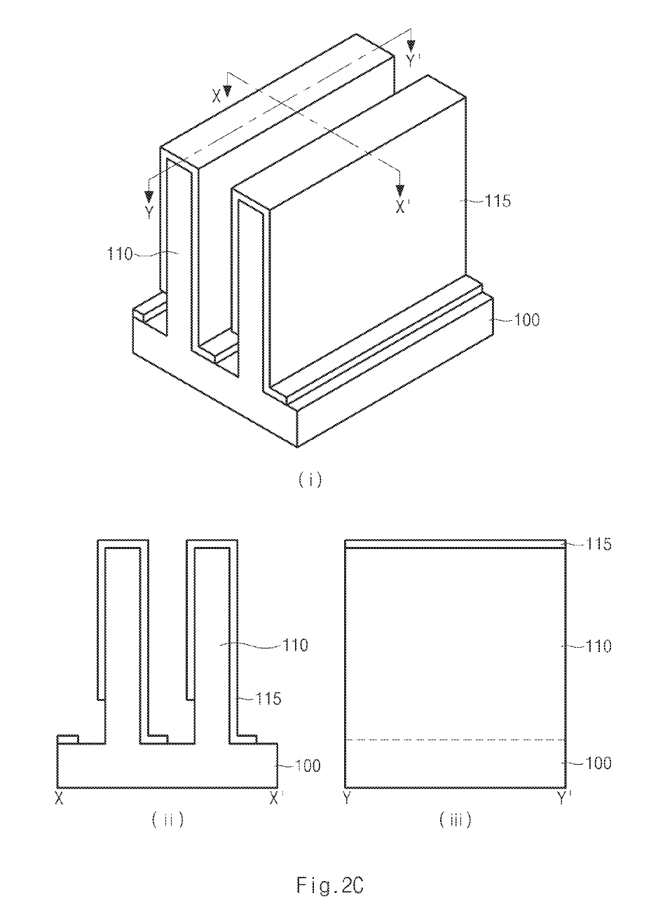

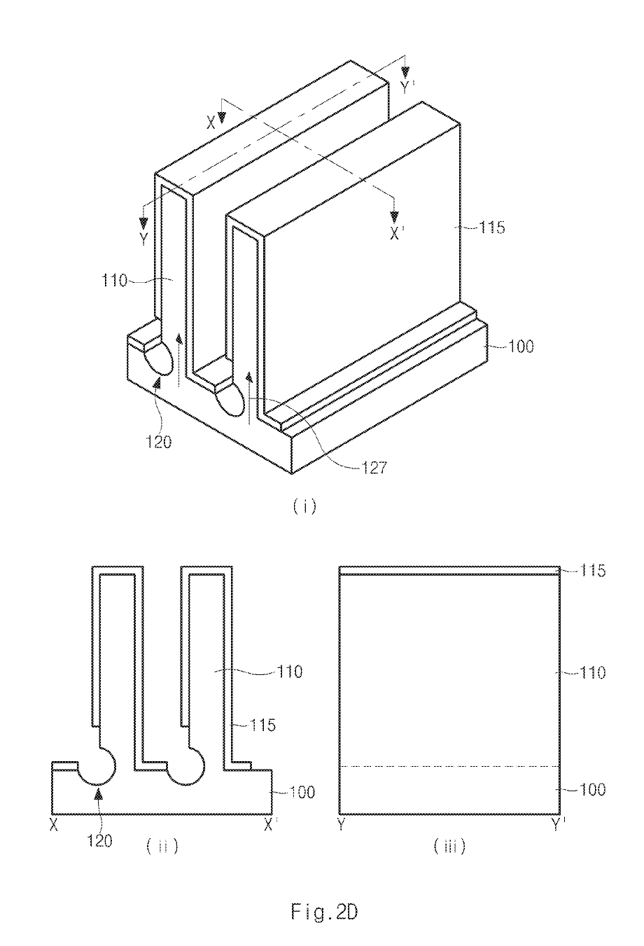

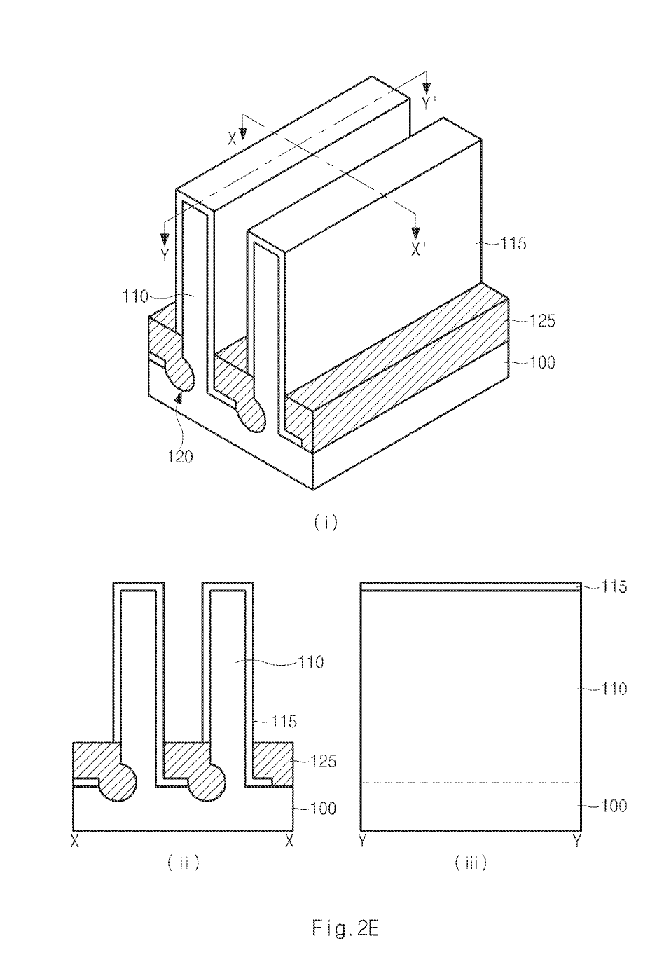

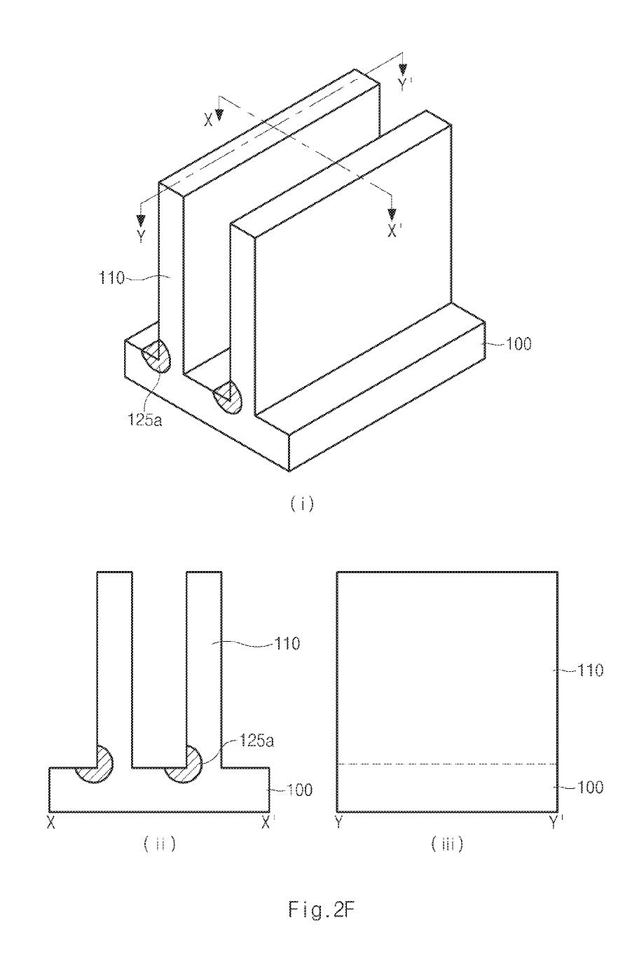

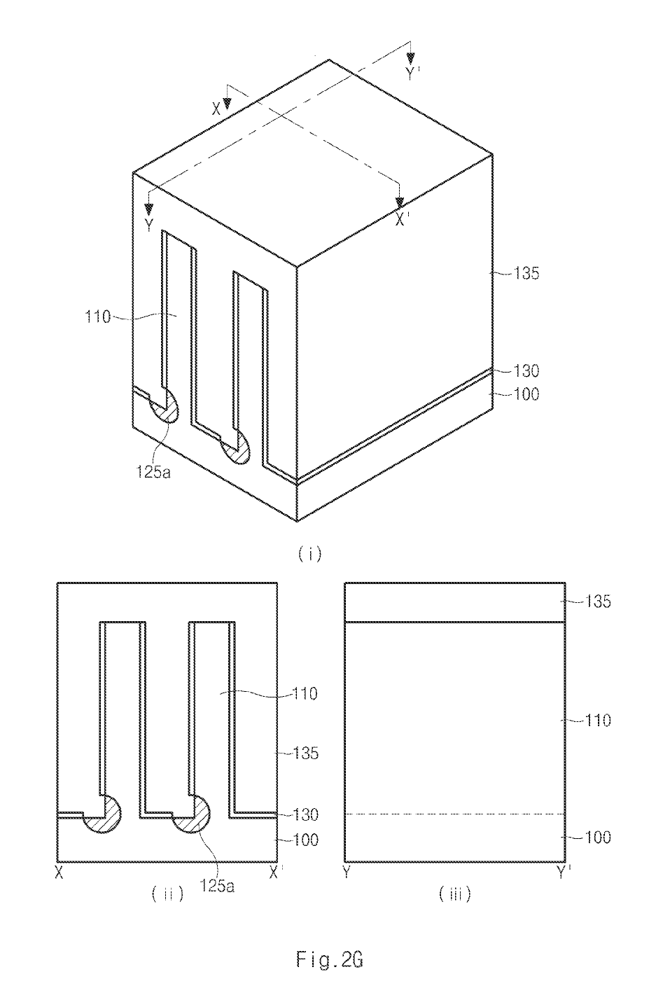

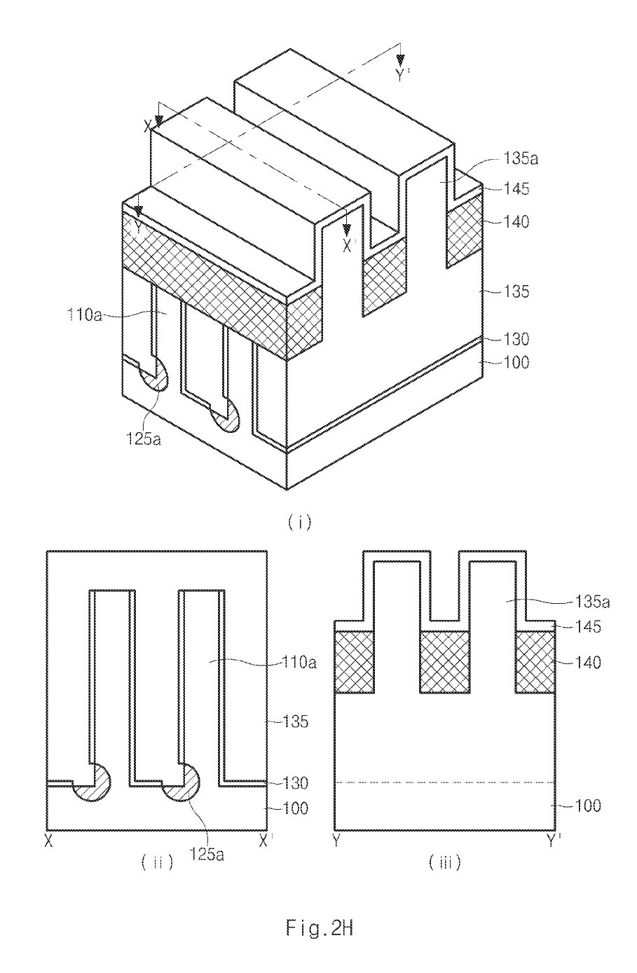

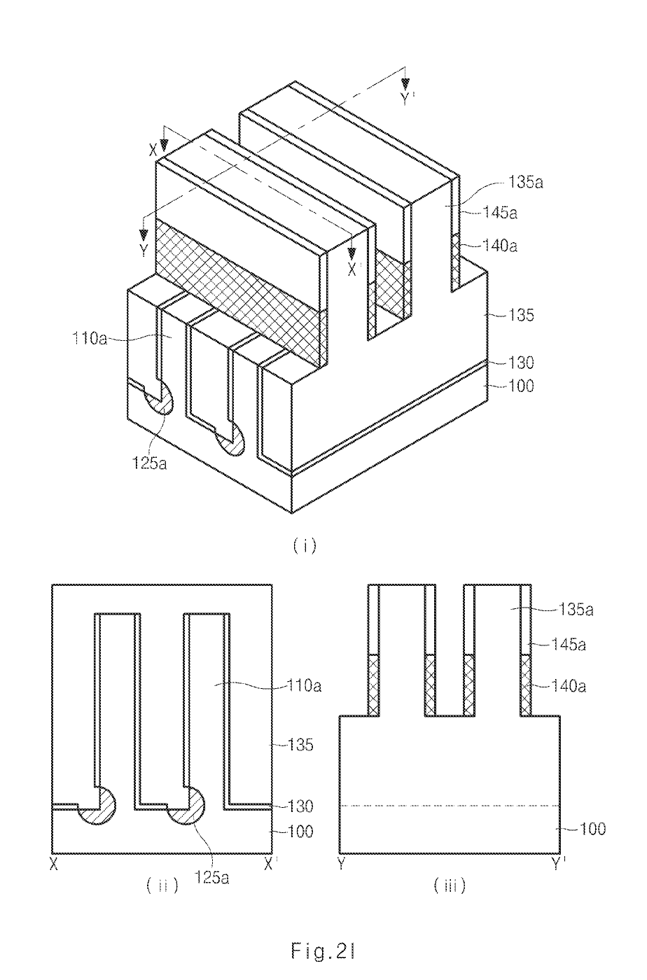

FIGS. 2A to 2I are perspective and cross-sectional views illustrating a method for manufacturing a semiconductor device according to an embodiment of the present invention. A method for manufacturing the semiconductor device including a vertical gate will hereinafter be described with reference to FIGS. 2A to 2I. In this case, FIGS. 2A(ii) to 2I(ii) are cross-sectional views illustrating the semiconductor device taken along the line X-X′ of FIGS. 2A(i) to 2I(i), and FIGS. 2A(iii) to 2I(iii) are cross-sectional views illustrating the semiconductor device taken along the line Y-Y′ of FIGS. 1A(i) to 2I(i).

Referring to FIG. 2A, a plurality of line patterns 110 may be formed by etching the semiconductor substrate 100. The line pattern 110 is extended in the Y-Y′ direction shown in FIG. 1 because some parts of the semiconductor substrate 100 are etched. Thereafter, a liner polysilicon layer 115 is deposited over the semiconductor substrate 100 including the line pattern 110. In this case, the liner polysilicon layer 115 may have a thickness of about 50 μm˜100 μm.

Referring to FIG. 2B, ions are implanted in the edge of one side of the line pattern 110 so that a doped polysilicon layer 115a is formed. The ion implantation process for forming the doped polysilicon layer 115a may be performed two times. During a primary ion implantation process, ions are implanted into a polysilicon layer 115 formed over the semiconductor substrate 100 interposed between the line patterns 110, and the ion implantation is performed at a tilt angle of about 5°˜10° with respect to the surface of the semiconductor substrate 100. Thereafter, a secondary ion implantation process is performed in the opposite direction to the primary ion implantation process, and ions are implanted in the polysilicon layer 115 formed at one sidewall of the bottom part of the line pattern 110. In this case, the secondary ion implantation process may be performed at a larger angle than the primary ion implantation process. For example, the secondary ion implantation process is performed at a tile angle of about 10°˜15° with respect to the surface of the semiconductor substrate 100. In addition, the secondary ion implantation process may be performed with energy not effecting the semiconductor substrate 100. For example, the secondary ion implantation process may be performed with an energy of about 2˜5 KeV.

Referring to FIG. 2C, the doped polysilicon layer 115a is removed so that the semiconductor substrate 100 and the line pattern 110 are exposed.

Referring to FIG. 2D, a bulb-shaped (or a round) recess 120 is formed by etching the exposed semiconductor substrate 100 and the line pattern 110. The recess 120 is formed by isotropic etching method for using the polysilicon layer 115 as an etch barrier. The recess 120 may also be formed in any other shapes other than the bulb shape without departing the scope or spirit of the present invention. Through the above-mentioned etching process, the recess 120 is formed only at the bottom of one side of the line pattern 110. In an embodiment, the recess 120 extends in the x direction such at the line pattern 110 remain in contact with the body of the semiconductor substrate 100 via a path 127 having sufficient width to prevent the line pattern 110 from experiencing the floating body effect.

Referring to FIG. 2E, a bit line conductive material 125 is formed over the entirety of the semiconductor substrate 100 including the recess 120. The bit line conductive material 125 may include any one of a titanium (Ti) film, a titanium nitride (TiN) film, a tungsten (W) film, and a combination thereof. Preferably, the bit line conductive material 125 may include a laminate structure of TiN film and Ti film, or a laminate structure of TiN film and tungsten (W) film. The conductive material 125 is etched by the etchback process, so that the conductive material 125 remains at a certain depth between the line patterns 110.

Referring to FIG. 2F, some parts of the polysilicon layer 115 and the bit line conductive material 125 are removed. Preferably, the removing process may be achieved by an anisotropic etching process, and may be etched until the line pattern 110 and the semiconductor substrate 100 are exposed. That is, the polysilicon layer 115 is completely removed, which is formed over the semiconductor substrate 100 including the line pattern 110. Also the bit line conductive material 125 is buried only in the recess 120. This buried bit line conductive material 125 is defined as a buried bit line 125a.

Referring to FIG. 2G, an oxide film 130 is deposited over the line pattern 110 including the bit line conductive material 125 and the entire surface of the semiconductor substrate 100. Thereafter, the planarized insulation film 135 is formed over the oxide film 130. The insulation film 135 may be formed of a material including an oxide film. For example, the oxide film may include at least one of a Spin On Dielectric (SOD), a High Density Plasma (HDP), and a combination thereof. More preferably, the SOD oxide film and the HDP oxide film are sequentially deposited.

Referring to FIG. 2H, a mask pattern (not shown) defining a gate is formed over the insulation film 135. The mask pattern (not shown) may be configured in the form of a line, and may be extended in the direction (See the direction Y-Y′ of FIG. 1) perpendicular to the buried bit line 125a. The insulation film 135 and the upper part of the line pattern 110 are etched so that an insulation film pattern 135a for opening a specific region in which the pillar pattern 110a and the gate are to be formed is formed. A gate conductive film 140 is formed over the entirety of the semiconductor substrate 100 including the insulation film pattern 135a.

Thereafter, the etchback process is performed so that the gate conductive film 140 remains only at the bottom part between the pillar patterns 110a. The spacer material 145 is deposited over the entire surface including the pillar pattern 110a and the gate conductive film 140. The spacer material 145 may include any one of an oxide film, a nitride film, and a combination thereof. More preferably, the nitride film and the oxide film may be sequentially formed. In this case, a thickness of the spacer material 145 is identical to a critical dimension (CD) of a gate to be formed in a subsequent process.

Referring to FIG. 2I, the etchback process is performed so that the spacer 145a is formed at sidewalls of the insulation film pattern 135a and the pillar pattern 110a. Subsequently, the gate conductive film 140 is etched using the spacer 145a as a mask, so that the gate 140a is formed at sidewalls of the insulation film pattern 135a.

As is apparent from the above description, since the bit line 125a is formed only on one side of the line pattern 110, a body tied structure for reducing the floating body effect in the typical vertical gate can be implemented.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

1. A semiconductor device comprising:
a semiconductor substrate having a body and a pillar pattern;
a bit line provided at a lower side of the pillar pattern and extending along a first direction, the bit line provided between the pillar pattern and the body of the substrate without isolating the pillar pattern from the body of the substrate; and
a gate pattern formed over the bit line and extending in a second direction different from the first direction.

2. The semiconductor device according to claim 1, wherein the pillar pattern is a semiconductor material formed by etching the semiconductor substrate, the pillar pattern extending upwardly from the body of the substrate.

3. The semiconductor device according to claim 1, wherein the bit line has a round shape.

4. The semiconductor device according to claim 1, wherein the bit line is formed of any one of a titanium (Ti) film, a titanium nitride (TiN) film, a tungsten (W) film, and a combination thereof.

5. The semiconductor device according to claim 1, wherein the bit line defines a path between the pillar pattern and the body of the substrate, the path being sufficiently wide to prevent the pillar pattern from experiencing floating body effect.

6. The semiconductor device according to claim 1, wherein the first direction and the second direction are orthogonal to each other.

7. The semiconductor device according to claim 1, wherein the gate pattern is provided at first and second sides of the pillar pattern.

8. The semiconductor device according to claim 7, further comprising a plurality of pillar patterns, wherein the gate pattern interconnects the plurality of pillar patterns.

9-20. (canceled)
